(19) United States
(12) Patent Application Publication
(10) Pub. No.: US 2026/0150682 A1
(43) Pub. Date: May 28, 2026

(54) ELECTRONIC PACKAGE STRUCTURE MANUFACTURING METHOD THEREOF

(71) Applicant: Acer Incorporated, New Taipei City (TW)

(72) Inventors: Kuan-Lin Chen, New Taipei City (TW); Mao-Neng Liao, New Taipei City (TW); Cheng-Wen Hsieh, New Taipei City (TW); Wei-Chin Chen, New Taipei City (TW); Kuang-Hua Lin, New Taipei City (TW); Tsung-Ting Chen, New Taipei City (TW); Yu-Ming Lin, New Taipei City (TW)

(73) Assignee: Acer Incorporated, New Taipei City (TW)

(21) Appl. No.: 19/392,167

(22) Filed: Nov. 18, 2025

(30) Foreign Application Priority Data
Nov. 27, 2024 (TW) 113145724

(51) Int. Cl. H01L 23/42; H01L 21/52; H01L 23/00; H01L 23/22; H01L 23/31; H01L 23/373; H01L 25/16

(52) U.S. Cl. CPC H10W 40/70; H10W 40/258; H10W 72/071; H10W 74/131; H10W 76/45; H10W 90/00; H10W 72/352; H10W 90/736

(57) ABSTRACT

Disclosed is an electronic package structure including a substrate, a first electronic element, at least one second electronic element, a wall, an electrically insulating glue, a liquid metal, and a heat dissipating member. The first electronic element and the second electronic element are disposed on the substrate respectively and adjoin each other. The wall disposed on the substrate surrounds the first and the second electronic elements. The electrically insulating glue is disposed on the substrate and filled between the first electronic elements and the wall to cover and seal the second electronic element. The liquid metal is disposed on the first electronic element. The heat dissipating member is disposed on the first electronic element and squeezes the liquid metal. Heat generated by the first electronic element is transferred to the heat dissipating member through the liquid metal. A manufacturing method of the electronic package structure is also provided.

### CROSS-REFERENCE TO RELATED APPLICATION

This application claims the priority benefit of Taiwan application Ser. No. 113145724, filed on Nov. 27, 2024. The entirety of the above-mentioned patent application is hereby incorporated by reference herein and made a part of this specification.

### BACKGROUND

### Technical Field

The disclosure relates to an electronic package structure and a manufacturing method thereof.

### Related Art

When operating at high speeds, a processor or an electronic elements inside an electronic device often generates a large amount of heat, which leads to a temperature rise in the processor or electronic element. An excessively high temperature may increase the power consumption of the processor or the electronic element, and even shorten a lifespan thereof. Therefore, heat dissipation is extremely important for the processor or electronic element inside the electronic device.

In the existing heat dissipation methods, the more common method is to use a thermal paste and a heat dissipating member, allowing the thermal paste to transfer heat from the processor or the electronic element to the heat dissipating member. The heat transfer and dissipation are enhanced by using a metal heat dissipating member which easily dissipate heat. However, a traditional viscous thermal paste has a low thermal conductivity coefficient and is unable to effectively transfer heat from the processor or the electronic element to the heat dissipating member. Therefore, a liquid metal thermal paste with a high thermal conductivity coefficient is gradually replacing the traditional thermal paste in a heat dissipation module of the electronic device.

Although the liquid metal thermal paste has the high thermal conductivity coefficient, the cohesive force of the liquid metal thermal paste is greater than the adhesive force between the liquid metal thermal paste and the surface of the processors or the electronic element, so that it is difficult to evenly apply the liquid metal thermal paste on the surface of the processor or the electronic element. Moreover, if the amount of the liquid metal thermal paste is not carefully controlled, the liquid metal thermal paste may overflow from the surface of the processor or the electronic element to cause a short circuit in surrounding circuits.

### SUMMARY

The disclosure provides an electronic package structure and a manufacturing method thereof, to provide a stable heat dissipation mechanism for protecting electronic elements and circuits.

An electronic package structure of the disclosure includes a substrate, a first electronic element, at least one second electronic element, a wall, an electrically insulating glue, a liquid metal, and a heat dissipating member. The first electronic element and the second electronic element are disposed on the substrate respectively and adjoin each other. The wall is disposed on the substrate and surrounds the first electronic element and the second electronic element. The electrically insulating glue is disposed on the substrate and located between the first electronic element and the wall. The electrically insulating glue covers and seals the second electronic element. The liquid metal is disposed on the first electronic element. The heat dissipating member is disposed on the first electronic element and squeezes the liquid metal. Heat generated by the first electronic element is transferred to the heat dissipating member through the liquid metal.

A manufacturing method of an electronic package structure of the disclosure includes as follows. The first electronic element and the second electronic element are packaged on the substrate respectively. The wall is disposed on the substrate, and makes the wall surround the first electronic element and the second electronic element. The electrically insulating glue is disposed on the substrate and filled between the first electronic element and the wall to cover and seal the second electronic element. After the electrically insulating glue is cured, the liquid metal is disposed on the first electronic element. The heat dissipating member is disposed on the first electronic element and squeezes the liquid metal.

Based on the above, the electronic package structure and the manufacturing method thereof provide a stable heat dissipation mechanism for electronic elements and circuits through convenient and effective protective measures. The wall is first disposed around the first electronic element and the second electronic element, and then the electrically insulating glue is filled in the space between the wall and the first electronic element to cover and seal the second electronic element. In this way, the second electronic element may be protected by the electrically insulating glue. Subsequently, when the liquid metal is disposed on the first electronic element and the heat dissipating member is disposed on the first electronic element and squeezes the liquid metal, any liquid metal which overflows from the first electronic element may be blocked by the aforementioned electrically insulating glue, which effectively prevents the overflowing liquid metal from contacting the second electronic element to cause a short circuit.

### BRIEF DESCRIPTION OF THE DRAWINGS

FIG. 1 is a top view of an electronic package structure according to an embodiment of the disclosure.

FIG. 2 is a partial sectional view of the electronic package structure in FIG. 1.

FIG. 3 is a flow chart of a manufacturing method of an electronic package structure.

FIG. 4A to FIG. 4D are simple schematic views of the manufacturing method in FIG. 3.

FIG. 5 is a partial sectional view of an electronic package structure according to another embodiment of the disclosure.

### DESCRIPTION OF THE EMBODIMENTS

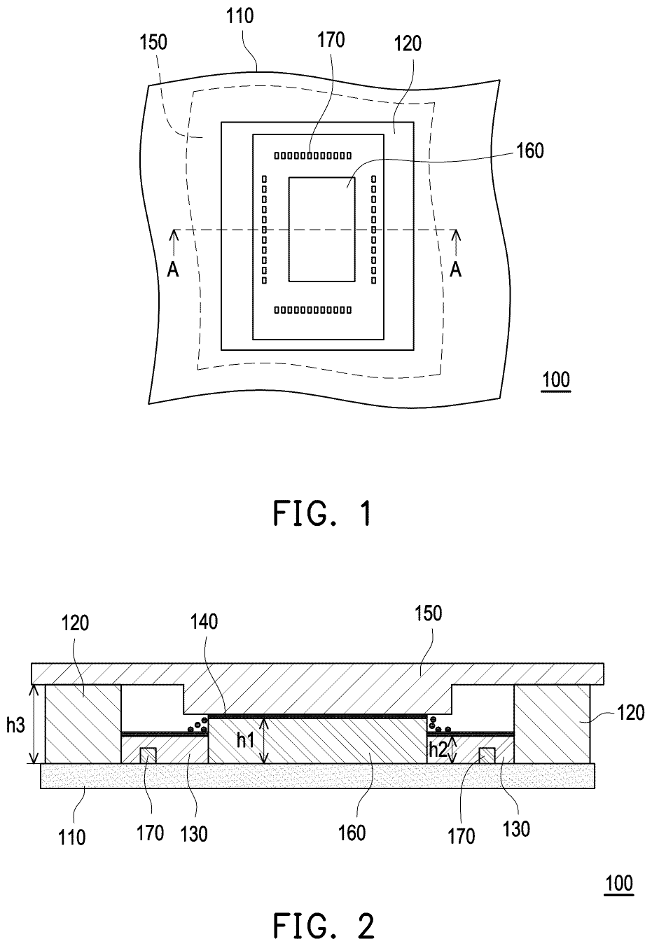

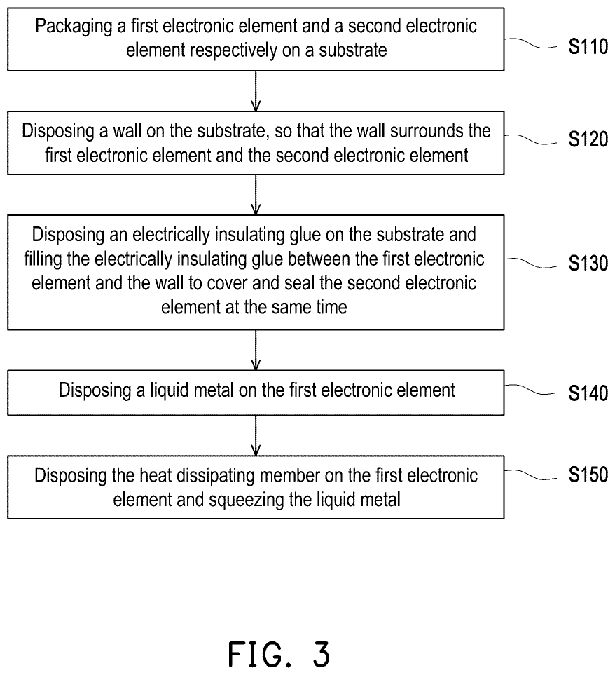

FIG. 1 is a top view of an electronic package structure according to an embodiment of the disclosure. FIG. 2 is a partial sectional view of the electronic package structure in FIG. 1, which is formed along a section line A-A shown in FIG. 1. Please refer to FIG. 1 and FIG. 2 together. In this embodiment, an electronic package structure 100 includes a substrate 110, a first electronic element 160, at least one second electronic element 170, a wall 120, an electrically insulating glue 130, a liquid metal 140, and a heat dissipating member 150. The first electronic element 160 and the second electronic element 170 are disposed on the substrate 110 respectively and adjoin each other. Here, the first electronic element 160 may include active elements such as a central processing unit (CPU) and a graphics processing unit (GPU), while the second electronic element 170 may include passive elements such as a capacitor, a resistor, and an inductor. In an embodiment, a number of second electronic elements 170 may be multiple, and the second electronic elements 170 surround the first electronic element 160. In another embodiment, the second electronic element 170 may include a multi-layer ceramic capacitor (MLCC), but the disclosure is not limited thereto. The substrate 110, for example, is a motherboard which carries the aforementioned electronic elements, with multiple circuits (not shown) disposed thereon.

Moreover, the wall 120 is disposed on the substrate 110 and surrounds the first electronic element 160 and the second electronic element 170. The electrically insulating glue 130 is disposed on the substrate 110 and is located between the first electronic element 160 and the wall 120. The electrically insulating glue 130 covers and seals the second electronic element 170. The liquid metal 140 is disposed on the first electronic element 160. The heat dissipating member 150 is disposed on the first electronic element 160 and squeezes the liquid metal 140, where the liquid metal 140 may possibly be squeezed and overflow from the first electronic element 160. Based on the aforementioned element configuration, the heat generated by the first electronic element 160 may be transferred to the heat dissipating member 150 through the liquid metal 140, and then dissipated from the electronic package structure 100 by the heat dissipating member 150.

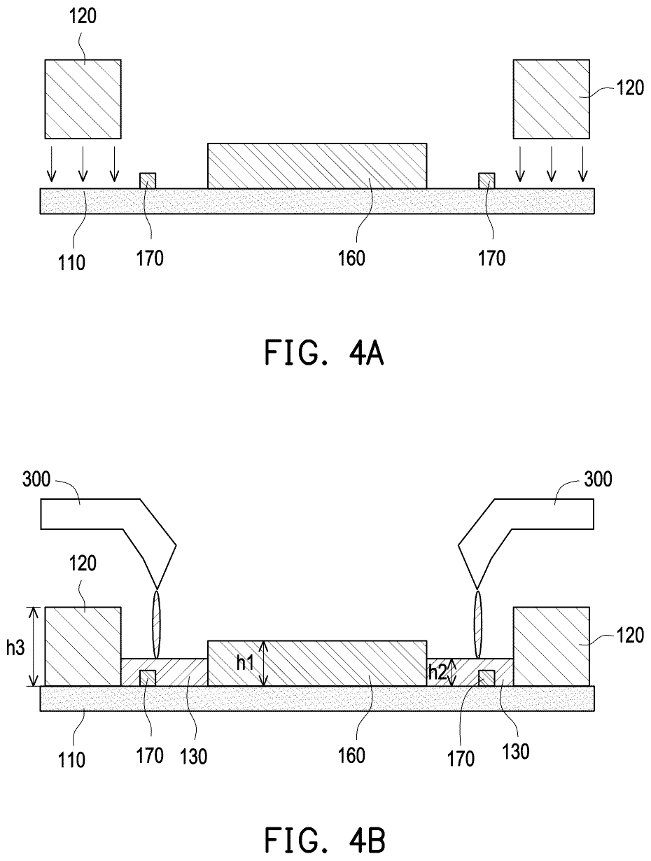

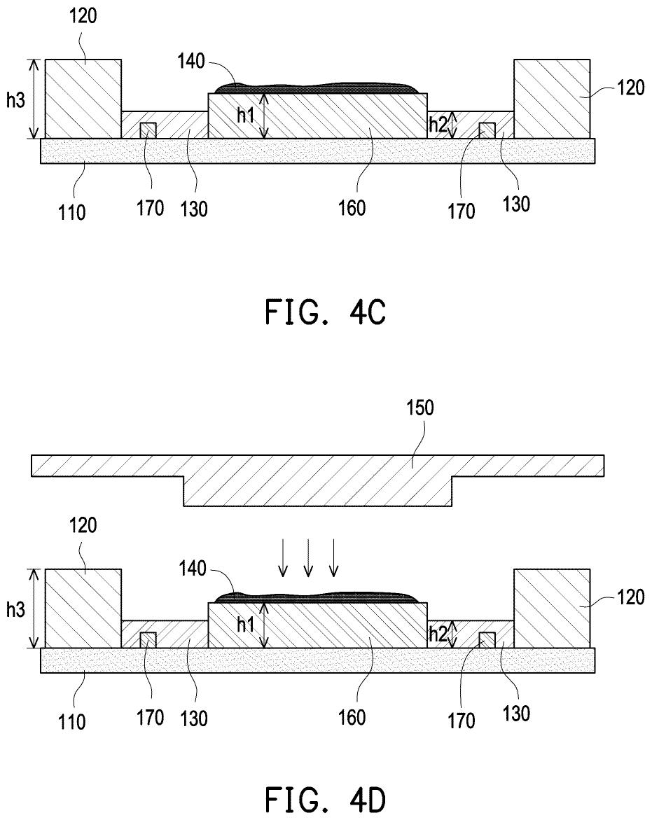

FIG. 3 is a flow chart of a manufacturing method of an electronic package structure. FIG. 4A to FIG. 4D are simple schematic views of the manufacturing method in FIG. 3. Please refer to FIG. 3 and correspond to the respective schematic diagrams of FIG. 4A to FIG. 4D. To achieve the component relationships of the aforementioned electronic package structure 100, first, in step S110, the first electronic element 160 and the second electronic element 170 are packaged on the substrate 110 respectively. Then, in step S120, as shown in FIG. 4A, the wall 120 is disposed on the substrate 110, and surrounds the first electronic element 160 and the second electronic element 170, as shown in FIG. 1. Next, in step S130 and as shown in FIG. 4B, the electrically insulating glue 130 is disposed on the substrate 110 and filled between the first electronic element 160 and the wall 120 by a glue dispenser 300 to cover and seal the second electronic element 170 at the same time. Subsequently, in step S140 and as shown in FIG. 4C, after the electrically insulating glue 130 is cured, the liquid metal 140 is disposed on the first electronic element 160. Finally, in step S150 and as shown in FIG. 4D, the heat dissipating member 150 is disposed on the first electronic element 160 and squeezes the liquid metal 140, and thus, the liquid metal 140 is squeezed and overflows from the first electronic element 160, as shown in the aforementioned FIG. 2.

It should also be mentioned that, in this embodiment, the wall 120 disposed in step S120 may be made of different materials according to requirements. Simply put, the wall 120 may be considered as a functional accessory of the electronic package structure 100. In an embodiment, the wall 120 is a cushion member, to be pressed against between the heat dissipating member 150 and the substrate 110, and configured to bear the pressure applied when the heat dissipating member 150 is assembled, which ensures that an internal space between the heat dissipating member 150 and the substrate 110 may be sealed due to the wall 120. In other words, a sealed space is formed by the substrate 110, the wall 120, and the heat dissipating member 150, thereby avoiding overflow outside the wall 120 during the steps of disposing the electrically insulating glue 130 or the liquid metal 140. In another embodiment, the wall 120 is an electromagnetic wave absorbing member to block interference between an electromagnetic wave from an external environment and an electromagnetic wave from the first electronic element 160. Furthermore, in another embodiment, the wall 120 may be made of a material with a high thermal conductivity coefficient to facilitate heat transfer from the substrate 110 to the heat dissipating member 150.

It should also be mentioned that, in this embodiment, in step S130 of disposing the electrically insulating glue 130, in addition to making the electrically insulating glue 130 cover the second electronic element 170, it is also necessary to make a thickness h2 of the second electronic element 170 smaller than the thickness h1 of the first electronic element 160, and a thickness h3 of the aforementioned wall 120 is greater than the thickness h1 of the first electronic element 160, where the preferable thickness h2 is 0.1 mm. Moreover, the electrically insulating glue 130 in this embodiment may be a conformal coating, with a viscosity less than 2000 cP at 25° C. As such, the glue dispenser 300 in step S130 further needs to adopt a screw applicator or piezoelectric sprayer to dispose the electrically insulating glue 130, to improve the precision of the glue layer (thickness and position) by controlling the amount of the applied glue. Furthermore, taking a polyurethane conformal coating as an example, the time of surface drying and curing at room temperature is about 30 minutes, while the complete curing time is 24 to 48 hours. Of course, the polyurethane conformal coating may also be cured by heating, for example, at 60° C. for 30 minutes and then removed, followed by 2 hours at room temperature to achieve complete curing. In another aspect, if an ultraviolet (UV) conformal coating is adopted, complete curing may be achieved within a few minutes by an ultraviolet light equipment. The selection and curing conditions of the aforementioned electrically insulating glue 130 may be appropriately adjusted according to requirements.

It should also be mentioned that, in this embodiment, the heat dissipating member 150 disposed in step S150 may be a copper heat dissipating board, with another side opposite to the liquid metal 140 which may be additionally equipped with a heat sink (such as a finned heat sink, a fan, or a related heat dissipating device, not shown here) to facilitate heat transfer out of the electronic package structure 100. Meanwhile, to avoid corrosion due to direct contact between the copper heat dissipating board and the liquid metal 140, an anti-corrosion metal layer is also provided on a surface of the copper heat dissipating board to serve as an isolation layer for the copper heat dissipating board. Moreover, the liquid metal 140 may be a low-melting-point alloy which is liquid at room temperature, or a solid sheet which becomes liquid when heated to a melting point. The composition of the liquid metal 140 may be gallium-indium-tin alloy, indium-bismuth-tin alloy, or indium-bismuth-zinc alloy, and the liquid metal 140 may be stable in nature and possess excellent thermal conductivity (a thermal conductivity coefficient of 30˜40W/m·K) and electrical conductivity. The liquid metal 140 is liquid at room temperature, offering convenience in operation, that is, after applied with the liquid metal 140, at least one of the heat dissipating member 150 and the first electronic element 160 may smoothly cover and squeeze the liquid metal 140, so that the liquid metal 140 spreads easily in the space between the heat dissipating member 150 and the first electronic element 160. Here, the thickness of the liquid metal 140 after disposing is 0.1 mm to 0.2 mm, to achieve the effects of reducing thermal resistance and rapidly transferring heat.

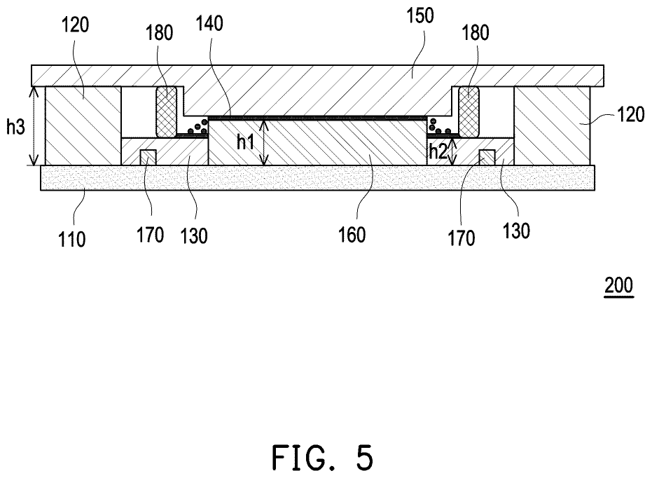

FIG. 5 is a partial sectional view of an electronic package structure according to another embodiment of the disclosure. Please refer to FIG. 5. Different from the aforementioned embodiments, an electronic package structure 200 of this embodiment further includes a sponge 180 disposed between the heat dissipating member 150 and the electrically insulating glue 130 and configured to block and absorb the liquid metal 140 which overflows from the first electronic element 160 due to the squeezing of the heat dissipating member 150. In this embodiment, the sponge 180 may be first disposed on the heat dissipating member 150, and when the heat dissipating member 150 is disposed on the first electronic element 160 in the aforementioned step S150, the sponge 180 is also attached to the electrically insulating glue 130. Here, the sponge 180 also has a buffering characteristic, and therefore may generate a sealing property like the wall 120. Meanwhile, when the liquid metal 140 overflows from the first electronic element 160 due to the squeezing of the heat dissipating member 150, the sponge 180 may effectively block and absorb the liquid metal 140, thereby limiting the liquid metal 140 in the space between the heat dissipating member 150, the sponge 180, the electrically insulating glue 130, and the first electronic element 160.

In summary, the electronic package structure and the manufacturing method thereof of the disclosure provide a stable heat dissipation mechanism for electronic elements and circuits through convenient and effective protective measures. The wall is first disposed around the first electronic element and the second electronic element, and then the electrically insulating glue is filled in the space between the wall and the first electronic element to cover and seal the second electronic element.

In addition, during a process of manufacturing the electronic package structure, the wall may be selected from materials with different functions according to functional requirements. Moreover, to effectively control the thickness of the electrically insulating glue on the substrate, a screw applicator or a piezoelectric sprayer is adopted to make the thickness of the electrically insulating glue less than the thickness of the first electronic element, and also because the thickness of the wall is greater than the thickness of the first electronic element, the electrically insulating glue may not overflow outside the electronic package structure. In another aspect, the electronic package structure further includes a sponge disposed on the heat dissipating member, squeezed on the electrically insulating glue along with the heat dissipating member, and configured to block and absorb the liquid metal which overflows from the first electronic element.

As a result, the second electronic element may be protected by the electrically insulating glue. Subsequently, when the liquid metal is disposed on the first electronic element and the heat dissipating member is disposing on the first electronic element and squeezes the liquid metal, the liquid metal which overflows from the first electronic element may be blocked by the aforementioned electrically insulating glue, which effectively prevents the liquid metal which overflows from the first electronic element from contacting the second electronic element to cause a short circuit.

What is claimed is:

1. An electronic package structure, comprising:
a substrate;
a first electronic element, disposed on the substrate;
at least one second electronic element, disposed on the substrate and adjoining the first electronic element;
a wall, disposed on the substrate and surrounding the first electronic element and the second electronic element;
an electrically insulating glue, disposed on the substrate and located between the first electronic element and the wall to cover and seal the second electronic element;
a liquid metal, disposed on the first electronic element; and
a heat dissipating member, disposed on the first electronic element and squeezing the liquid metal, wherein heat generated by the first electronic element is transferred to the heat dissipating member through the liquid metal.

2. The electronic package structure according to claim 1, wherein a thickness of the electrically insulating glue is less than a thickness of the first electronic element, and the thickness of the first electronic element is less than a thickness of the wall.

3. The electronic package structure according to claim 1, wherein a thickness of the electrically insulating glue is 0.1 mm.

4. The electronic package structure according to claim 1, wherein the first electronic element is a processor, and the second electronic element is a capacitor.

5. The electronic package structure according to claim 1, wherein the electrically insulating glue is a conformal coating.

6. The electronic package structure according to claim 1, wherein a viscosity of the electrically insulating glue is less than 2000 cP at 25°C.

7. The electronic package structure according to claim 1, further comprising:
a sponge, disposed between the heat dissipating member and the electrically insulating glue, and configured to block and absorb the liquid metal which overflows from the first electronic element due to squeezing of the heat dissipating member.

8. The electronic package structure according to claim 1, wherein the wall is a cushion member, and is pressed against between the heat dissipating member and the substrate.

9. The electronic package structure according to claim 1, wherein the wall is a heat conducting member, and transfers heat from the substrate to the heat dissipating member.

10. The electronic package structure according to claim 1, wherein the wall is an electromagnetic wave absorbing member to block interference between an electromagnetic wave from an external environment and an electromagnetic wave from the first electronic element.

11. The electronic package structure according to claim 1, wherein the substrate, the wall, and the heat dissipating member form a sealed space.

12. A manufacturing method of an electronic package structure, comprising:
packaging a first electronic element and a second electronic element on a substrate respectively;
disposing a wall on the substrate, and making the wall surround the first electronic element and the second electronic element;
disposing an electrically insulating glue on the substrate and filling the electrically insulating glue between the first electronic element and the wall to cover and seal the second electronic element;
disposing a liquid metal on the first electronic element after the electrically insulating glue is cured; and
disposing a heat dissipating member on the first electronic element and squeezing the liquid metal.

13. The manufacturing method of the electronic package structure according to claim 12, further comprising:
disposing a sponge on the heat dissipating member, so that when the heat dissipating member squeezes the liquid metal, the sponge blocks and absorbs the liquid metal which overflows from the first electronic element.

14. The manufacturing method of the electronic package structure according to claim 12, wherein the electrically insulating glue is applied to the substrate and covers the second electronic element by a screw applicator or a piezoelectric sprayer, and a thickness of the electrically insulating glue is 0.1 mm.

15. The manufacturing method of the electronic package structure according to claim 12, wherein when the heat dissipating member is disposed on the first electronic element, the heat dissipating member presses against the wall.

16. The manufacturing method of the electronic package structure according to claim 12, wherein a thickness of the wall is greater than a thickness of the first electronic element, and a thickness of the electrically insulating glue is less than the thickness of the first electronic element.
